(19) United States
(12) Patent Application Publication
(10) Pub. No.: US 2008/0221346 A1
(43) Pub. Date: Sep. 11, 2008

(54) Oriented-film formation apparatus and oriented film

(75) Inventor: Takuya Miyakawa, Matsumoto (JP)

Correspondence Address: HARNESS, DICKEY & PIERCE, P.L.C., P.O. BOX 828, BLOOMFIELD HILLS, MI, 48303, US

(73) Assignee: Seiko Epson Corporation

(21) Appl. No.: 12/075,061

(22) Filed: Mar. 6, 2008

(30) Foreign Application Priority Data
Mar. 9, 2007 (JP) 2007-060298

(51) Int. Cl. C07F 7/02; C23C 16/00

(52) U.S. Cl. 556/450; 118/726

(57) ABSTRACT

An oriented-film formation apparatus forms an oriented film on a substrate by obliquely evaporating a predetermined material in a vacuum state and includes an evaporation source having an organic-inorganic hybrid material.

### CROSS-REFERENCE TO RELATED APPLICATION

This application is based on and claims priority from Japanese Patent Application No. 2007-060298, filed on Mar. 9, 2007, the contents of which are incorporated herein by reference.

### BACKGROUND

1. Technical Field

The present invention relates to an oriented-film formation apparatus and an oriented film.

2. Related Art

A liquid crystal device is known to be used as a light-modulation device included in a projection display device, a direct-view display device included in a portable telephone, or the like.

As this liquid crystal device, for example, a construction is known in which a liquid crystal layer is interposed between a pair of substrates arranged facing each other.

In this construction, an electrode for applying voltage to the liquid crystal layer is formed on a surface close to the liquid crystal layer of these substrates.

In the liquid crystal device, an oriented film for controlling the predetermined arrangement of liquid crystal molecules at the non-voltage application time is formed to be in contact with the liquid crystal layer on the one pair of substrates.

In the liquid crystal device, a display is performed on the basis of an arrangement variation of liquid crystal molecules at the voltage application time and the non-voltage application time.

Conventionally, as the above-mentioned oriented film, an oriented film in which a surface of an organic film made of polyimide or the like is rubbed in a predetermined direction with a cloth or the like is widely used in that the orientation regulating force for the liquid crystal molecules is superior.

For example, such an oriented film is disclosed in Japanese Unexamined Patent Application, First Publication No. H3-215832.

However, there is a problem in that display quality is degraded since a streak is formed on a film surface when applying a rubbing treatment to the organic film and the streak is shown on a display surface.

Moreover, there is a problem in that cloth fragments acting as particles are adhered to the oriented film surface, resulting in the yield degradation for the oriented film.

On the other hand, there has been proposed a method for forming an oriented film on a substrate by obliquely evaporating a polymer material on the substrate.

According to this method, the degradation of display quality or the degradation of yield may be prevented since a rubbing treatment does not need to be performed.

However, the oriented film is cracked and low molecularized by heating when the oriented film is made of the polymer material.

For this reason, there is a problem in that characteristics of the oriented film vary with temperature since the composition of the polymer material installed as an evaporation source deteriorates according to temperature or the like and is evaporated on the substrate.

That is, the method for forming the oriented film by evaporating the conventional polymer material on the substrate has a problem that reproducibility of the desired characteristics of the oriented film formed is low.

### SUMMARY

An advantage of some aspects of the invention is to provide an oriented-film formation apparatus that forms an oriented film on a substrate by obliquely evaporating a predetermined material of the evaporation source in vacuum state and that forms the oriented film having the desired characteristics with a high level of reproducibility.

A first aspect of the invention provides an oriented-film formation apparatus forming an oriented film on a substrate by obliquely evaporating a predetermined material in a vacuum state, the oriented-film formation apparatus including an evaporation source having an organic-inorganic hybrid material.

In the oriented-film formation apparatus of the first aspect of the invention, the organic-inorganic hybrid material is used as the evaporation source.

The organic-inorganic hybrid material has both an organic component and an inorganic component in the same molecule. Since the organic-inorganic hybrid material has an inorganic backbone, it is a material of higher heat resistance than when compared to a polymer material.

By using this organic-inorganic hybrid material as the evaporation source, the deterioration of a material composition can be prevented in an evaporation process in comparison with a conventional oriented-film formation apparatus using the polymer material as the evaporation source.

Therefore, according to the oriented-film formation apparatus of the first aspect of the invention, by obliquely evaporating the material of the evaporation source on the substrate, it is possible to form the oriented film having the desired characteristics with a high level of reproducibility in the oriented-film formation apparatus for forming the oriented film.

Furthermore, the oriented film made of the organic-inorganic hybrid material has a superior heat resistance. Therefore, even if the oriented film is subjected to in a high-temperature environment and in a process of manufacturing a liquid crystal device, the deterioration of composition of the oriented film can be prevented.

It is preferable that, in the oriented-film formation apparatus of the first aspect of the invention, the melting point of the organic-inorganic hybrid material be higher than the temperature at which the oriented film is subjected to in a process of manufacturing a liquid crystal device having the oriented film.

In the oriented-film formation apparatus including the above constitution, the oriented film made of the organic-inorganic hybrid material can prevent the orientation regulating force from being lost due to melting in the process of manufacturing the liquid crystal device.

It is preferable that, in the oriented-film formation apparatus of the first aspect of the invention, the molecular weight of the organic-inorganic hybrid material be the molecular weight so that the composition of the organic-inorganic hybrid material does not deteriorate in the vacuum state.

By adopting the above constitution, it is possible to prevent the deterioration of composition of the organic-inorganic hybrid material in the vacuum state. Therefore, even if the oriented film is subjected to in the high-temperature environment, the further deterioration of composition of the oriented film can be reliably prevented.

It is preferable that, in the oriented-film formation apparatus of the first aspect of the invention, the organic-inorganic hybrid material include silsesquioxanes.

The silsesquioxanes are materials superior in both heat resistance and light resistance. Therefore, by using the silsesquioxanes as the organic-inorganic hybrid material, it is possible to form the oriented film superior in both heat resistance and light resistance with a high level of reproducibility.

A second aspect of the invention provides an oriented film used for a liquid crystal device, including an organic-inorganic hybrid material.

The oriented film of the second aspect of the invention including the above constitution is superior in heat resistance.

It is preferable that, in the oriented film of the second aspect of the invention, the organic-inorganic hybrid material include silsesquioxanes.

By adopting the above constitution, the oriented film of the second aspect of the invention is superior in both heat resistance and light resistance.

### BRIEF DESCRIPTION OF THE DRAWINGS

FIG. 1 is a view showing an equivalent circuit in a liquid crystal device.

FIG. 2 is an enlarged plan view showing a structure of pixel groups adjacent to each other in a TFT array substrate.

FIG. 3 is an enlarged cross-sectional view showing an element structure of the liquid crystal device.

FIG. 4 is an enlarged cross-sectional view showing a construction of a pixel region.

FIG. 5A is a cross-sectional schematic view illustrating a construction of an example of an oriented-film formation apparatus, FIG. 5B is a perspective view showing an evaporation source.

FIG. 6 is a cross-sectional view showing a construction of an oriented-film formation apparatus having an adhesion resistant plate.

FIG. 7A is a cross-sectional view showing a construction of an oriented-film formation apparatus having a correcting plate and a point evaporation source.

FIG. 7B is a plan view showing a construction of an oriented-film formation apparatus having a correcting plate and a point evaporation source.

FIG. 8 is a view showing an example of a projection display device having a liquid crystal device.

### DESCRIPTION OF EXEMPLARY EMBODIMENTS

Hereinafter, an embodiment of an oriented-film formation apparatus and an oriented film according to the invention will be described with reference to the drawings.

The scale of pieces is suitably changed to show the pieces in recognizable sizes in the drawings.

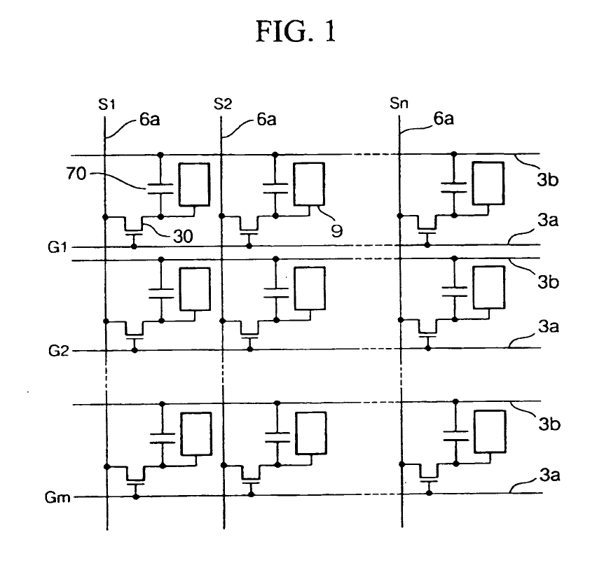

FIG. 1 shows an equivalent circuit of a switching element, a signal line, and the like in a plurality of pixels arranged in a grid-like arrangement (matrix formation) constructing an image display region of a transmission-type liquid crystal device of this embodiment.

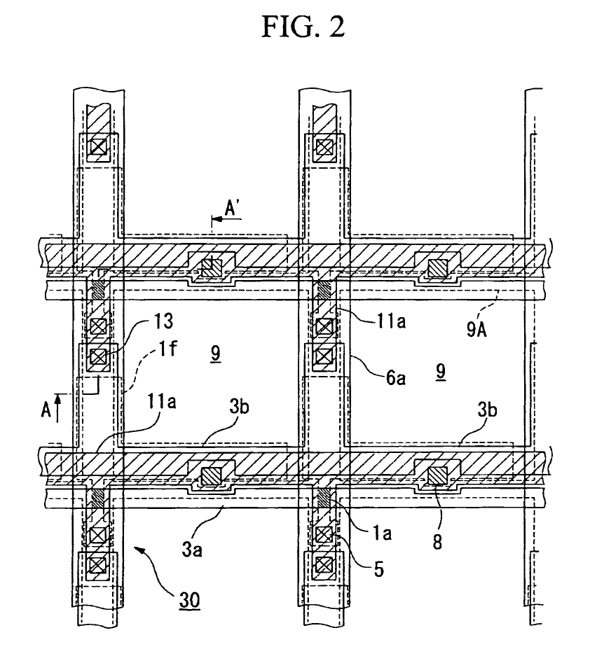

FIG. 2 shows an enlarged structure of a plurality of pixel groups adjacent to each other in a TFT (Thin Film Transistor) array substrate in which a data line, a scanning line, a pixel electrode, and the like are formed.

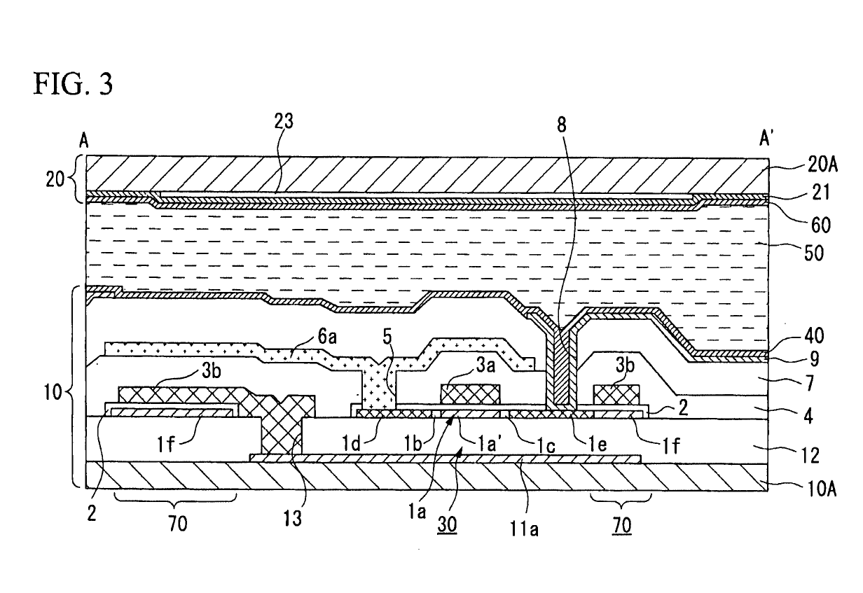

FIG. 3 is an enlarged cross-sectional view showing an element region for the transmission-type liquid crystal device of this embodiment, and is a cross-sectional view taken along the line A-A′ of FIG. 2.

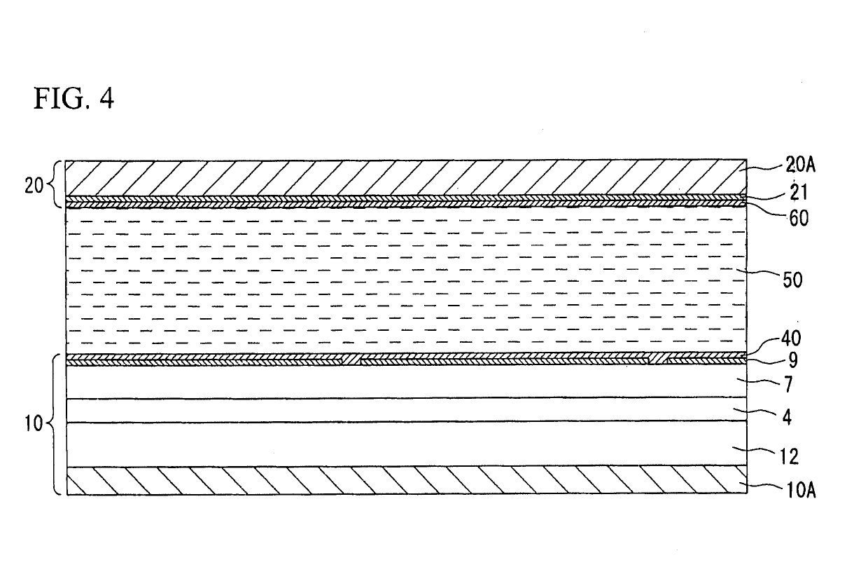

FIG. 4 is a cross-sectional view schematically showing a plurality of pixel regions for the transmission-type liquid crystal device of this embodiment

In FIGS. 3 and 4, there is shown the case where the top side of the view is the side of light incidence, and the bottom side of the view is the observation side (observer side).

As shown in FIG. 1 in the transmission-type liquid crystal device of this embodiment, a pixel electrode 9 and a TFT element 30 serving as a switching element for controlling conductivity for the pixel electrode 9 are formed in a plurality of pixels arranged in the a grid-like arrangement constructing an image display region, and a data line 6a from which an image signal is supplied is electrically connected to a source of the TFT element 30.

Image signals S1, S2, - - - , Sn written in data lines 6a are line-sequentially supplied in this order, or are supplied on a group basis for a plurality of data lines 6a adjacent to each other.

A scanning line 3a is electrically connected to a gate of the TFT element 30, scanning signals G1, G2, - - - , Gm for a plurality of scanning lines 3a are line-sequentially applied in pulses at a predetermined timing.

The pixel electrode 9 is electrically connected to a drain of the TFT element 30, and the TFT element 30 serving as the switching element are turned on during a given time. The image signals S1, S2, - - - , Sn supplied from the data lines 6a are written at a predetermined timing.

The image signals S1, S2, - - - , Sn at a predetermined level written in the liquid crystal through the pixel electrodes 9 are held for a given period between the pixel electrodes 9 and a common electrode described below.

The liquid crystal modulates the light and enables the gradation display by varying the orientation or order of the molecular aggregates according to the applied voltage level.

In order to prevent leakage of the held image signals, accumulative capacities 70 are added in parallel to liquid crystal capacities formed between the pixel electrodes 9 and the common electrode.

Next, a planar structure of the transmission-type liquid crystal device of this embodiment will be described with reference to FIG. 2.

As shown in FIG. 2, a plurality of rectangular pixel electrodes 9 (of which contours are shown by broken lines 9A) made of a transparent conductive material, such as Indium Tin Oxide (hereinafter, referred to as ITO), are provided in a grid-like arrangement on a TFT array substrate, and data lines 6a, the scanning lines 3a and capacity lines 3b are provided along vertical and horizontal boundaries of the pixel electrodes 9.

In this embodiment, regions where the pixel electrodes 9 and the data lines 6a, the scanning lines 3a, and the capacity lines 3b arranged to surround the pixel electrodes 9 are formed are pixels, and the pixels arranged in the a grid-like arrangement have a structure capable of performing a display.

The data lines 6a are electrically connected to a source region described below in a semiconductor layer 1a made of, for example, a polysilicon film, constructing the TFT elements 30 via a contact hole 5, and the pixel electrodes 9 are electrically connected to a drain region described below in the semiconductor layer 1a via a contact hole 8.

The scanning lines 3a are arranged to face a channel region described below in the semiconductor layer 1a (a region of oblique lines rising to the left in the figure), and the scanning lines 3a function as a gate electrode at a portion facing the channel region.

The capacity lines 3b have a main line part extending substantially linearly along the scanning line 3a (that is, as viewed in the vertical direction of the TFT array substrate, a first region formed along the scanning line 3a), and a projection portion projecting from a front stage side (upward in the figure) along the data line 6a from a point intersecting with the data line 6a (that is, as viewed in the vertical direction of the TFT array substrate, a second region provided extensively along the data line 6a).

In a region indicated by oblique lines rising to the right in FIG. 2, a plurality of first shading films 11a are provided.

Next, a cross-sectional structure of the transmission-type liquid crystal device of this embodiment will be described with reference to FIGS. 3 and 4.

In FIG. 4, some components such as switching elements and the like are omitted for visibility.

In the transmission-type liquid crystal device of this embodiment as shown in FIGS. 3 and 4, a liquid crystal layer 50 is interposed between a TFT array substrate 10 (substrate for a liquid crystal device) and a facing substrate 20 (substrate for a liquid crystal device) arranged facing the TFT array substrate 10.

The TFT array substrate 10 is mainly constructed with a substrate 10A made of a translucent material such as quartz or the like, a pixel electrode 9 formed on the surface of substrate 10A witch is close to the liquid crystal layer 50, and an oriented film 40 The facing substrate 20 is mainly constructed with a substrate 20A made of a translucent material such as glass, quartz, or the like, a common electrode 21 formed on the surface of substrate 20A witch is close to the liquid crystal layer 50, and an oriented film 60.

In the TFT array substrate 10 as shown in FIG. 3, the pixel electrode 9 is provided on the surface of substrate 10A witch is close to the liquid crystal layer 50, and at a position adjacent to each of the pixel electrode 9, a TFT element 30 for pixel switching which performs switching control over each pixel electrode 9 is provided.

The TFT element 30 for pixel switching has an LDD (Lightly Doped Drain) structure, and a scanning line 3a, a channel region 1a′ of the semiconductor layer 1a where a channel is formed by an electric field from the scanning line 3a, a gate insulating film 2 insulating the scanning line 3a and the semiconductor layer 1a, the data line 6a, a low-concentration source region 1b and a low-concentration drain region 1c of the semiconductor layer 1a, and a high-concentration source region 1d and a high-concentration drain region 1e of the semiconductor layer 1a.

On the substrate 10A including surfaces of the scanning line 3a and the gate insulating film 2, a second interlayer insulating film 4 is formed in which a contact hole 5 coupled to the high-concentration source region 1d and a contact hole 8 coupled to the high-concentration drain region 1e are opened

In other words, the data line 6a is electrically connected to the high-concentration source region 1d via the contact hole 5 penetrating the second interlayer insulating film 4.

On the data line 6a and the second interlayer insulating film 4, a third interlayer insulating film 7 is formed in which the contact hole 8 coupled to the high-concentration drain region 1e is opened.

That is, the high-concentration drain region 1e is electrically connected to the pixel electrode 9 via the contact hole 8 penetrating the second interlayer insulating film 4 and the third interlayer insulating film 7.

In this embodiment, the gate insulating film 2 is extended from a position facing the scanning line 3a and is used as a dielectric film, and the semiconductor film 1a is extended to serve as a first accumulative capacity electrode 1f, and a part of the capacitance line 3b facing these serves as a second accumulative capacity electrode, thereby constructing an accumulative capacity 70.

In a region formed by each TFT element 30 for pixel switching on the surface of substrate 10A of TFT array substrate 10 which is close to the liquid crystal layer 50, the first shading film 11a is provided whereby return light that transits the TFT array substrate 10, that is reflected on the shown bottom surface of the TFT array substrate 10 (the boundary face of the TFT array substrate 10 and air), and that returns toward the liquid crystal layer 50 is prevented from entering at least the channel region 1a′ and the low-concentration source and drain regions 1b and 1c of the semiconductor layer 1a.

Between the first shading film 11a and the TFT element 30 for pixel switching, a first interlayer insulating film 12 is formed to electrically insulate the semiconductor layer 1a, constructing the TFT element 30 for pixel switching, from the first shading film 11a.

As shown in FIG. 2, the first shading film 11a is provided in the TFT array substrate 10 and also the first shading film 11a is constructed to be electrically connected to a front or rear stage capacity line 3b via a contact hole 13.

On the top surface of TFT array substrate 10 which is close to the liquid crystal layer 50, that is, the pixel electrode 9 and the third interlayer insulating film 7, an oriented film 40 is formed to control the orientation of liquid crystal molecules within the liquid crystal layer 50 at the non-voltage application time.

This oriented film 40 is formed using an oriented-film formation apparatus and method thereof according to the invention described below.

On the other hand, in regard to the facing substrate 20, on the surface of substrate 20A which is close to the liquid crystal layer 50, in a region facing a formation region of the data line 6a, the scanning line 3a and the TFT element 30 for pixel switching, that is, a region other than an opening region of each pixel section, there is provided a second shading film 23 to prevent incident light from entering the channel region 1a′, the low-concentration source region 1b and the low-concentration drain region 1c of the semiconductor layer 1a of the TFT element 30 for pixel switching.

On the surface of substrate 20A which is close to the liquid crystal layer 50, on which the second shading film 23 is formed, the common electrode 21 made of ITO or the like is formed over substantially all the surface. In addition, on the surface which is closed to the liquid crystal layer 50, an oriented film 60 is formed to control the orientation of the liquid crystal molecules in the liquid crystal layer 50 at the non-voltage application time.

This oriented film 60 is also formed by an oriented-film formation apparatus and method thereof according to the invention described below.

Herein, the oriented films 40 and 60 are constructed with a film-like body formed by obliquely evaporating an organic-inorganic hybrid material.

The organic-inorganic hybrid material has both an organic component and an inorganic component in the same molecules and has an inorganic backbone. Therefore, this material has higher heat resistance and higher light resistance as compared to a polymer material.

The oriented films 40 and 60 are formed by obliquely evaporating the organic-inorganic hybrid material in a vacuum environment and have the orientation regulating force without performing a rubbing treatment

For this reason, in the transmission-type liquid crystal device of this embodiment, the improvement of display quality and the improvement of manufacturing efficiency of the liquid crystal device are accommodated since the degradation of display quality due to a streak formed on a film surface does not occur, and the degradation of yield associated with the rubbing treatment does not occur, when a conventional rubbing treatment is performed.

In this embodiment, a material of a high melting point (for example, 150° C. or more) and a low molecular weight (molecular weight that does not deteriorate in the vacuum evaporation) among organic-inorganic hybrid materials can be suitably used, and specifically, organic-inorganic hybrid materials of silsesquioxanes can be suitably used as shown in the following chemical formulas (1) to (72).

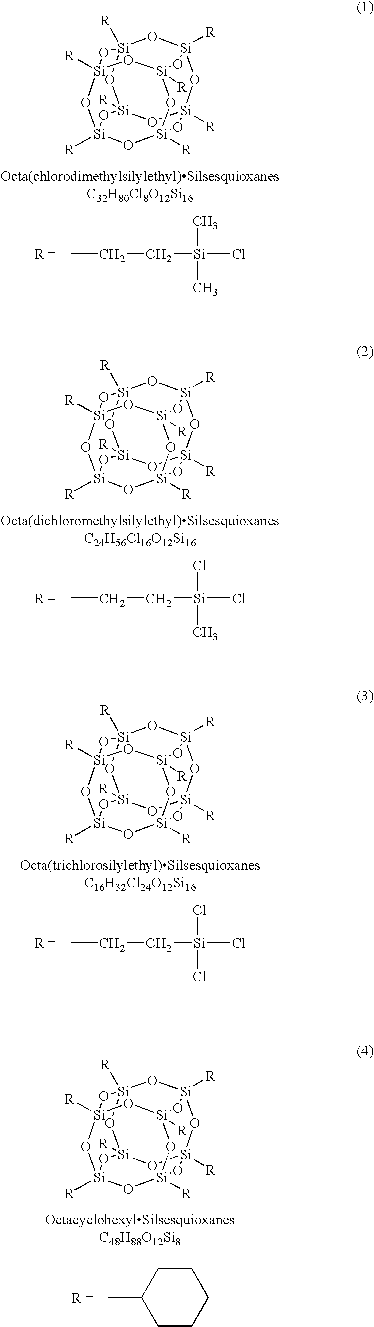

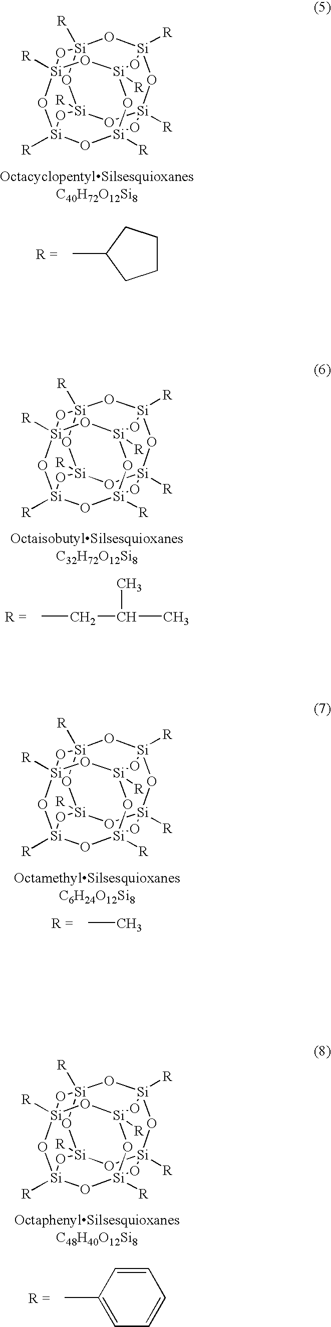

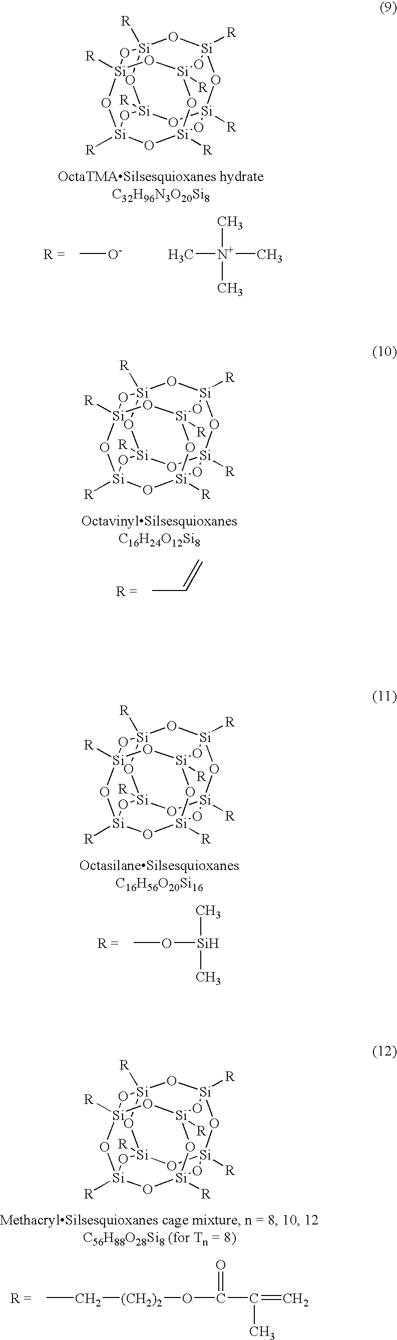

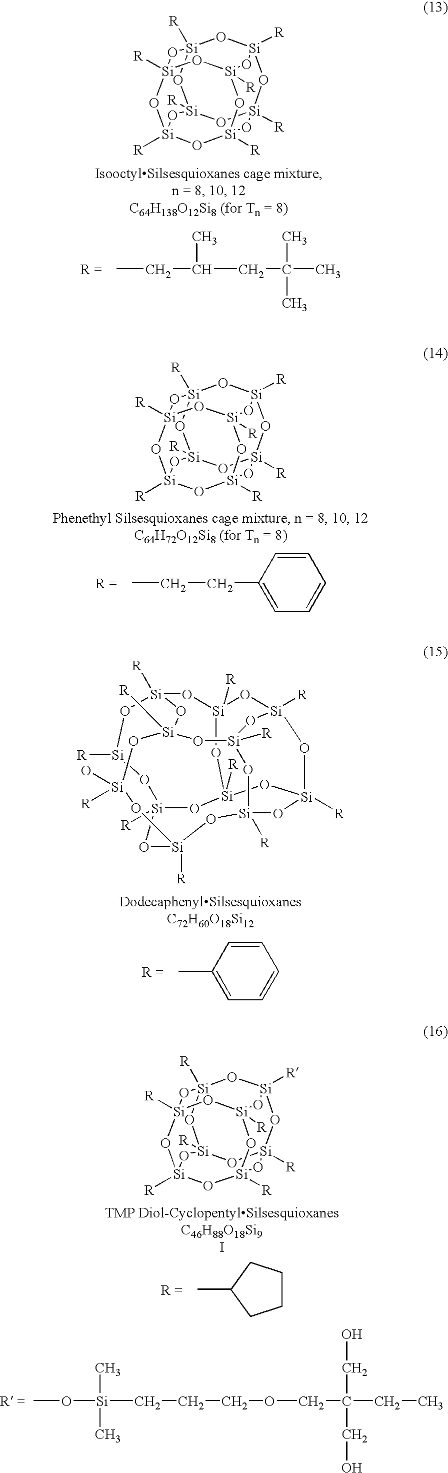

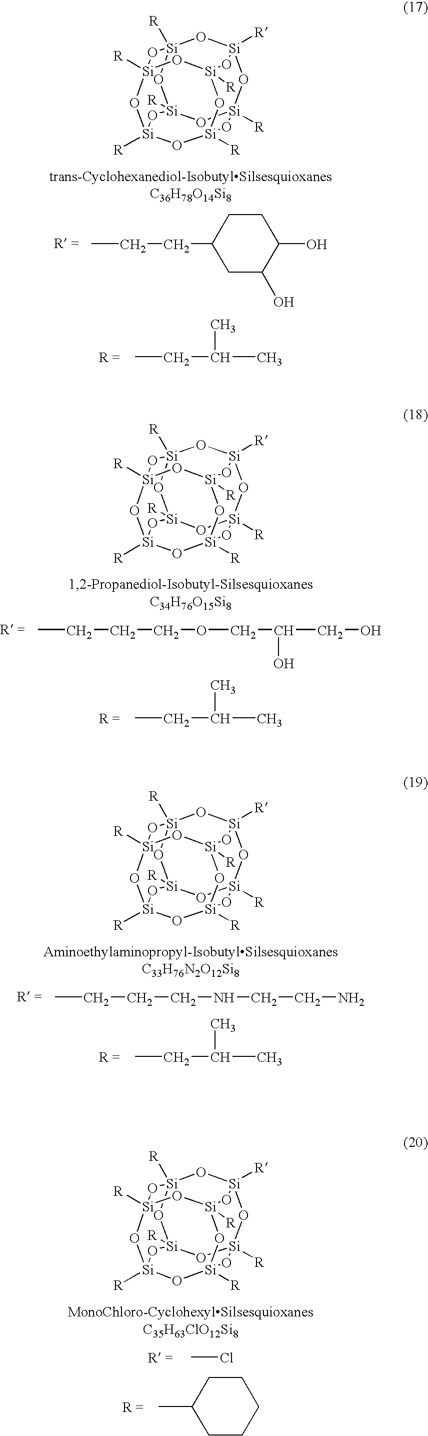

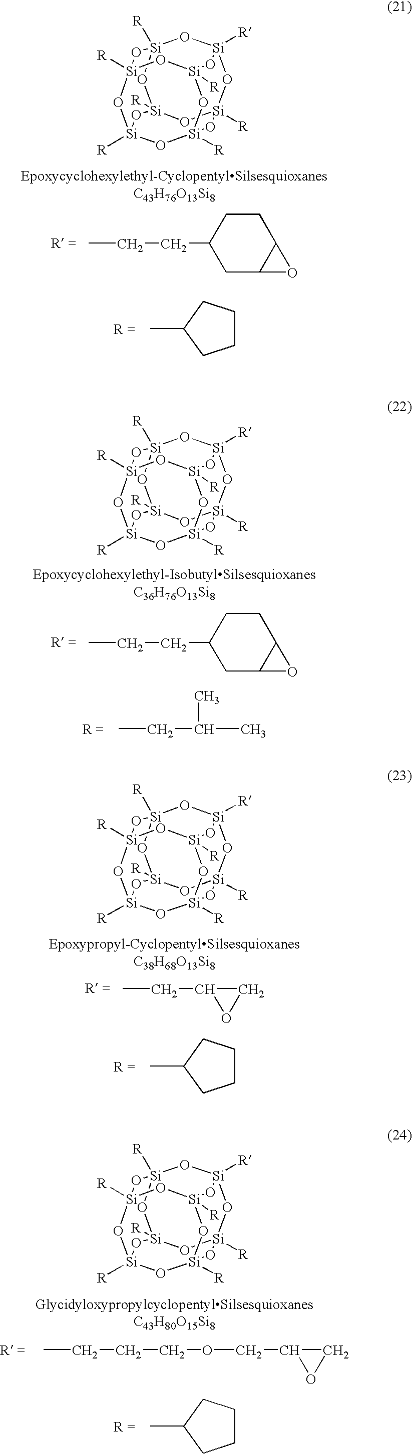

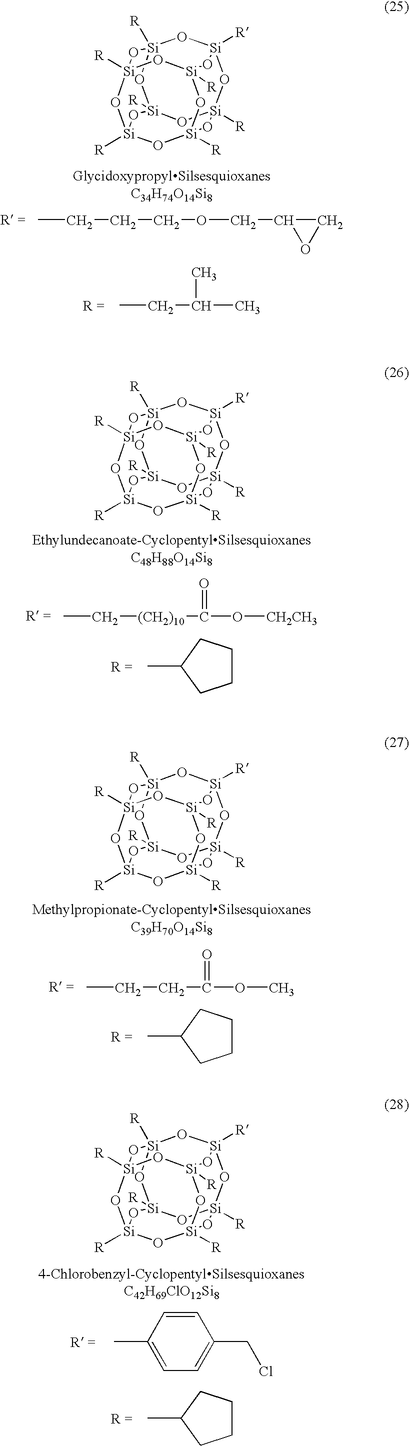

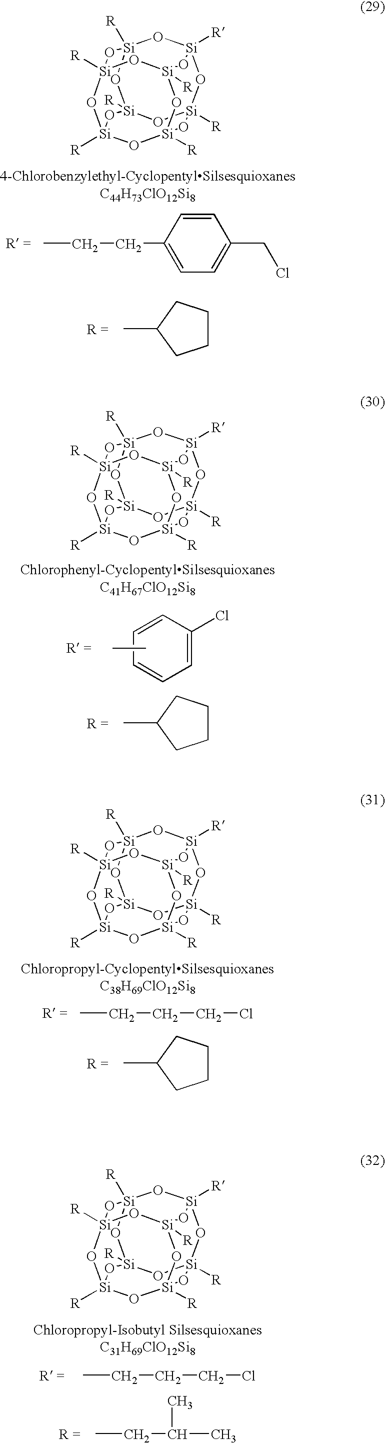

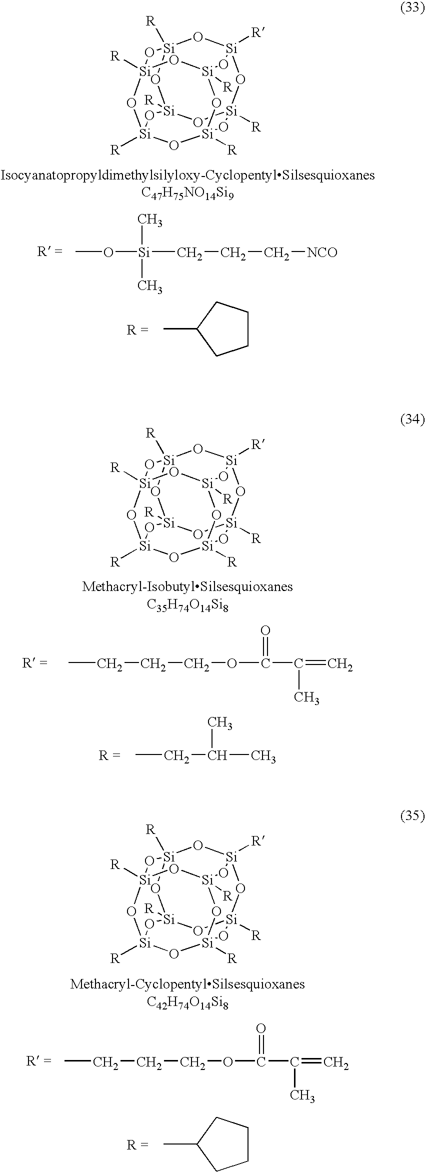

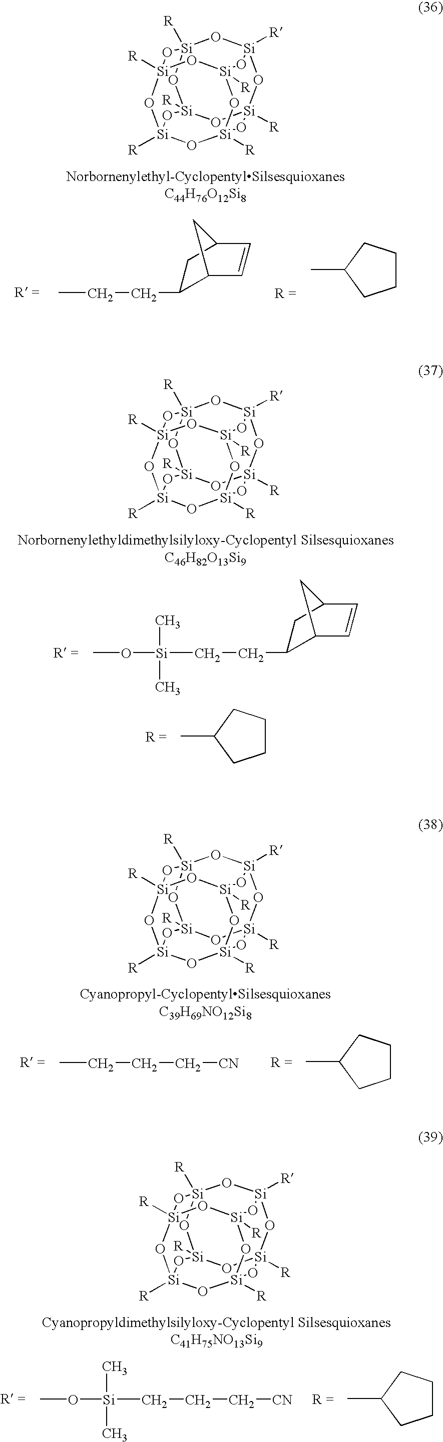

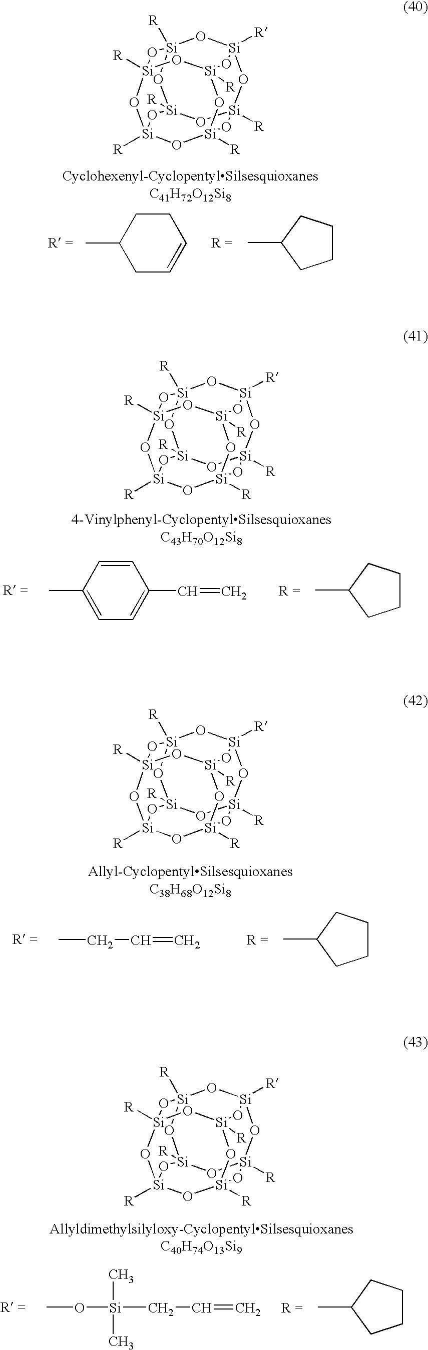

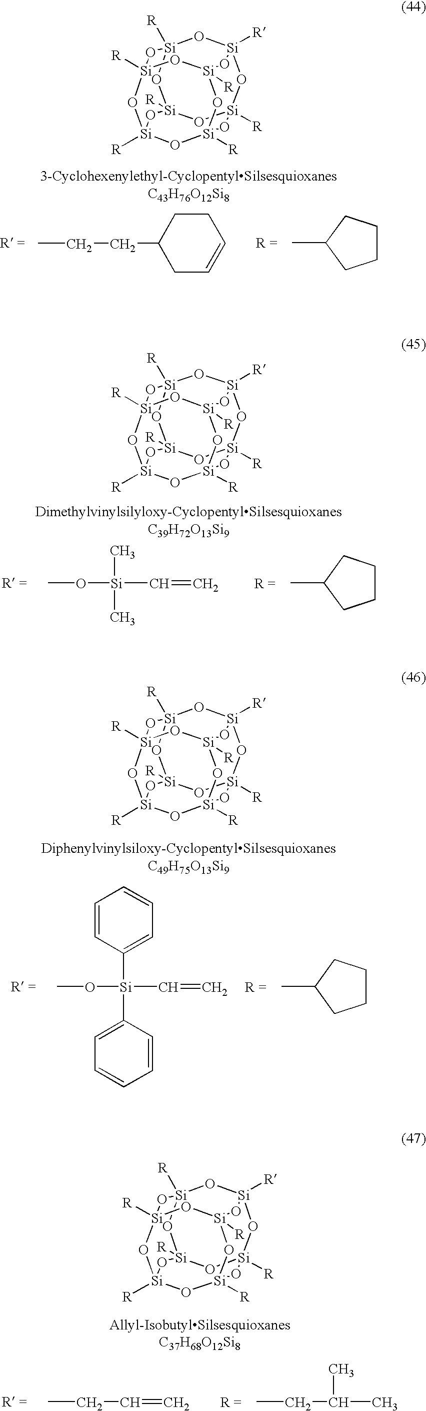

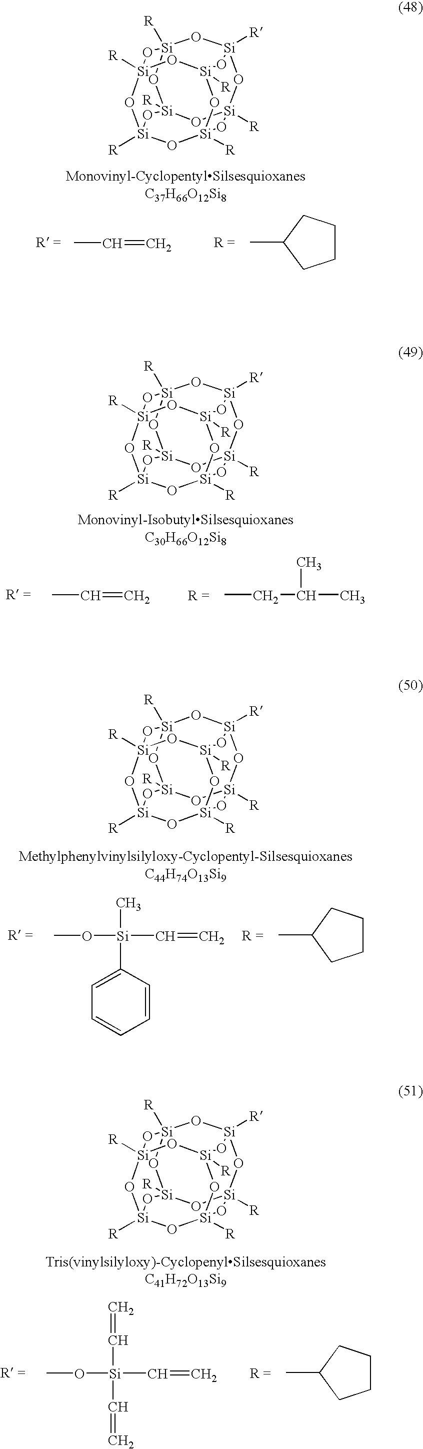

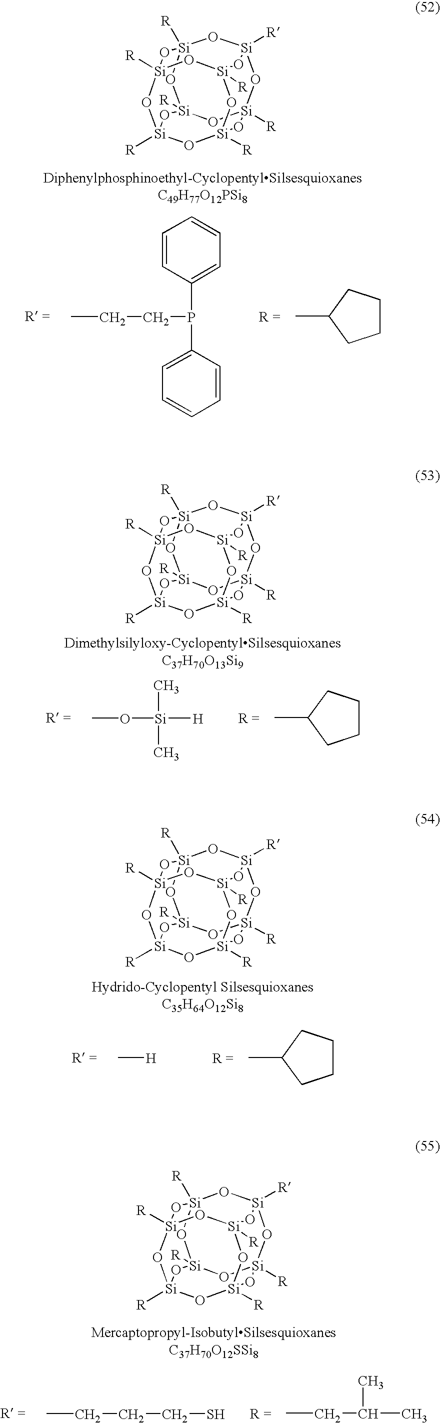

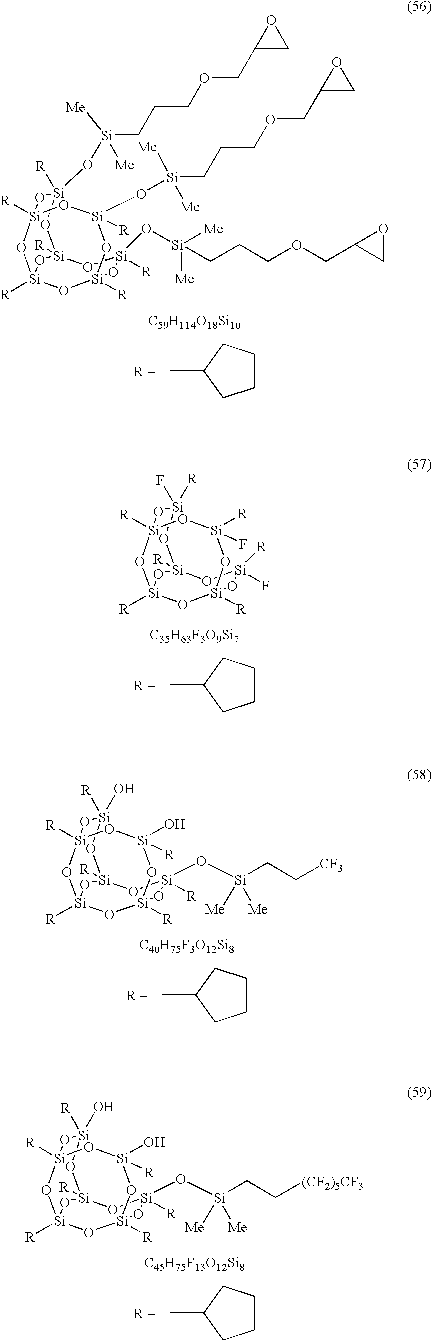

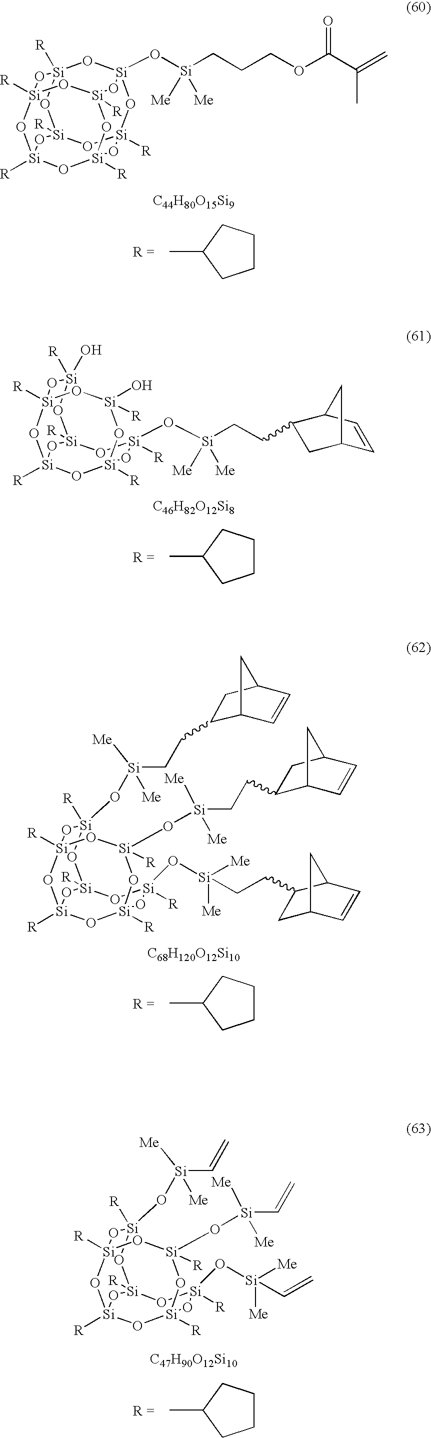

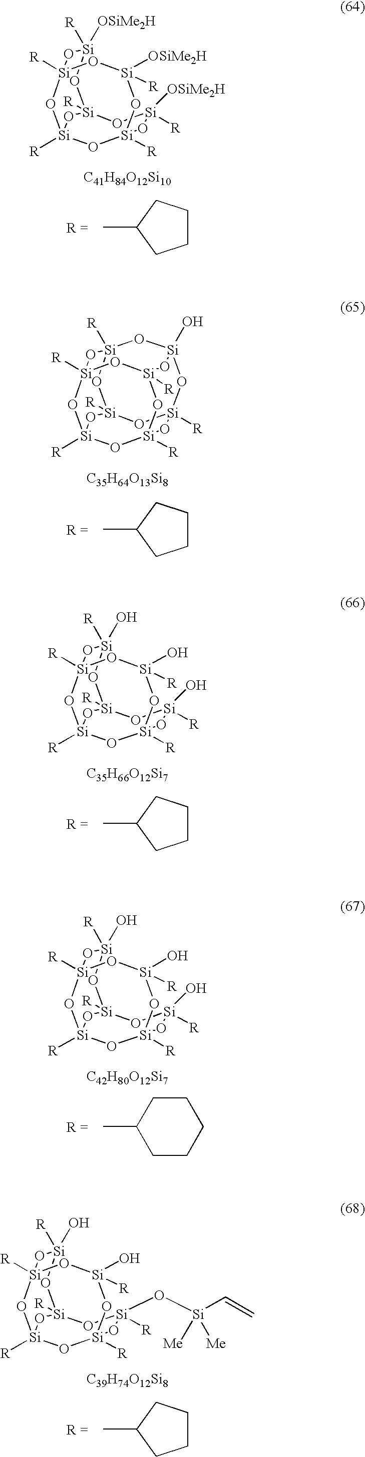

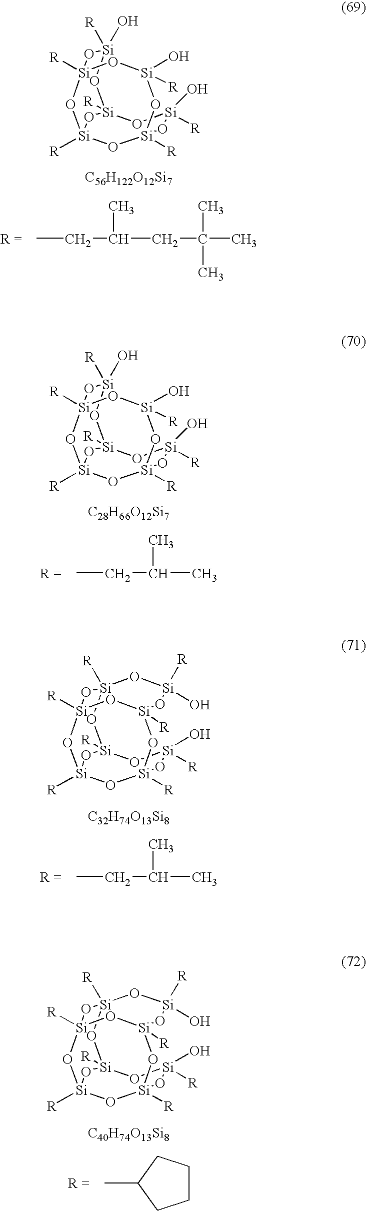

Next, a method for forming the oriented film 40 which is formed on the TFT array substrate 10 constructing the liquid crystal device 100 will be described as one embodiment of the oriented-film forming method.

Also, the oriented film 60 which is formed on the facing substrate 20 can be equally formed in the oriented-film forming method of the invention.

First, a translucent substrate 10A made of glass or the like is prepared and the first shading film 11a, the first interlayer insulating film 12, the semiconductor layer 1a, the wirings 3a, 3b, and 6a, the insulating films 4 and 7, the pixel electrode 9, and the like are formed therein by the known method

Thus, the oriented film 40 is formed on the third interlayer insulating film 7 including the pixel electrode 9.

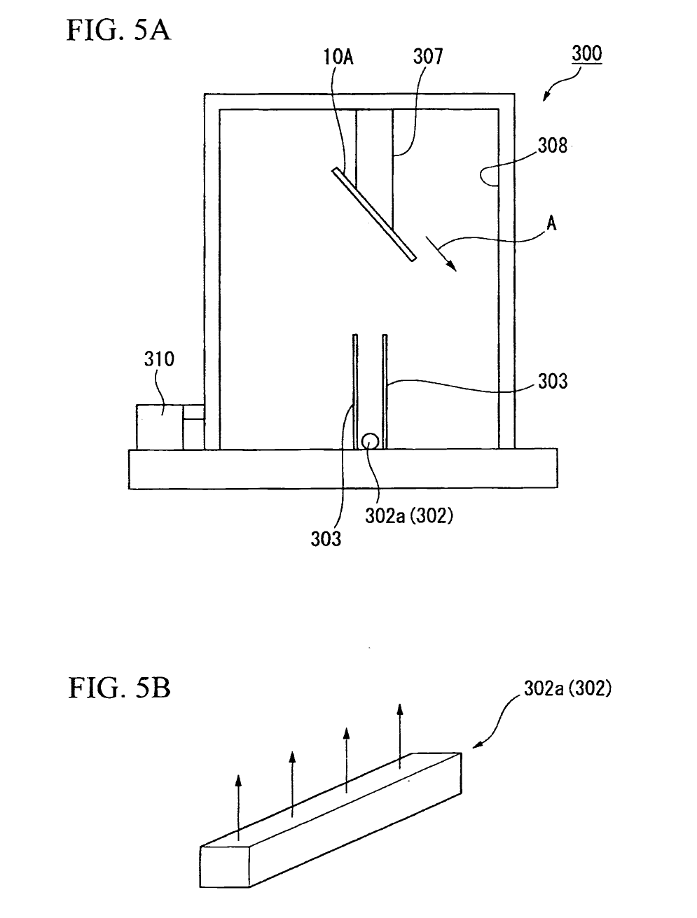

In this embodiment, the oriented film 40 is formed by an oriented-film formation apparatus 300 according to the invention as shown in FIGS. 5A and 5B using the above-described organic-inorganic hybrid material.

FIG. 5A is a schematic view illustrating an external appearance of the oriented-film formation apparatus 300 used to form the oriented film in this embodiment.

The oriented-film formation apparatus 300 includes an evaporation source 302 made of the above-described organic-inorganic hybrid material, an evaporation chamber 308 having a substrate holder 307 in which the substrate 10A is slanted and arranged at a predetermined angle to the evaporation source 302, and a vacuum pump 310 for forming a vacuum in the evaporation chamber 308.

The oriented-film formation apparatus 300 of this embodiment uses a linear evaporation source 302a as the evaporation source 302 as shown in FIG. 5B.

In this embodiment, organic-inorganic hybrid materials of silsesquioxanes having a high melting point and a low molecular weight are used as the organic-inorganic hybrid materials.

As shown in FIG. 5B, a material is diffused widely in a line direction (longitudinal direction) using the linear evaporation source 302a.

Therefore, the linear evaporation source 302a has a higher uniformity of material distribution as compared with the case where a point evaporation source in which a material is radially distributed is used Therefore, the material can be uniformly film-formed in the line direction.

The length of the linear evaporation source 302a is substantially the same as the width of the substrate 10A which is an evaporation object.

Accordingly, an oriented film made of the above-described organic-inorganic hybrid material can be formed on the substrate 10A by moving the substrate 10A in an arrow A direction of FIG. 5A with respect to the linear evaporation source 302a.

One pair of regulating plates 303 facing each other between which the linear evaporation source 302a is interposed are provided between the linear evaporation source 302a and the substrate 10A.

The regulating plates 303 are provided along the line direction, that is, the longitudinal direction of the linear evaporation source 302a as shown in FIG. 5B.

According to this construction, the diffusion of an evaporation material (organic-inorganic hybrid material) in a direction orthogonal to the line direction (longitudinal direction) is regulated with the regulating plate 303.

A heating section of a lamp heater (not shown) or the like is provided on an outer surface side of the regulating plate 303. Therefore, at least an inner surface side of the regulating plate 303 becomes a heated surface.

As the heating section, a resistance heating type in which a nichrome wire or the like is embedded in the regulating plate 303 can be adopted.

It is desirable that the temperature of the heated surface is adjusted so that a material is not adhered to the heated surface when the material evaporated from the linear evaporation source 302a collides with the heated surface.

Accordingly, when the evaporated material collides with the heated surface, the material is reflected without adherence to the inner surface (heated surface) of the regulating plate 303.

Furthermore, for film formation on the substrate 10A in a given directivity state, as described below, an end portion of the regulating plate 303 and the substrate 10A are separately arranged by a predetermined distance.

In this embodiment, the regulating plate 303 and the substrate 10A are separated by the interval less than or equal to 10 cm, using the regulating plate 303 which has a height of approximately 10 cm.

Under this construction, the oriented-film formation apparatus 300 of this embodiment can form an oriented film homogeneously made in a predetermined orientation on the substrate 10A.

Subsequently, a method for forming the oriented film on the substrate using the oriented-film formation apparatus 300 will be described.

First, the inside of the evaporation chamber 308 is in a vacuum state when the vacuum pump 310 is operated. The vapor of the organic-inorganic hybrid material is generated from the evaporation source 302 when the evaporation source 302 is heated by a heating apparatus (not shown).

Thus, a material diffused in a direction orthogonal to the line direction among materials from the evaporation source 302 is diffused into a region interposed between the regulating plates 303.

In this embodiment, the regulating plate 303 is formed in the line direction as described above. Therefore, the material is uniformly diffused in the line direction even when no regulating plate is provided since a line (linear evaporation source 302a) is used as the evaporation source 302.

The material diffused from the evaporation source 302 collides with the regulating plate 303.

At this time, since an inner surface side of the regulating plate 303 becomes the heated surface as described above, the material is reflected without adherence when colliding with the inner surface side of the regulating plate 303.

Thus, the collision and reflection of the material are repeated in the region interposed between the regulating plates 303. A material is thereby distributed and uniformly formed in the orthogonal direction of the regulating plate 303 (the orthogonal direction of the line direction).

That is, the material can form a homogeneous film-like body on the substrate 10A since the distribution in the above-described line direction and the direction orthogonal to the line direction is uniform.

After passing through the region interposed between the regulating plates 303, the material is evaporated on a surface of the substrate 10A at a predetermined angle.

Herein, the material passed through the regulating plates 303 has a uniform distribution, but irregularity in the directivity of particles occurs.

In this apparatus 300, the material out of a desired direction is not film-formed on the substrate 10A since the end portion of the regulating plate 303 and the substrate 10A are separately arranged by the predetermined distance as described above. Therefore, an oriented film having a predetermined directivity can be formed on the substrate 10A.

Accordingly, a material whose distribution is uniformly formed by the regulating plate 303 is film-formed on the substrate. An oriented film having a high level of reliability in which a material having a constant thickness is oriented in an evaporation direction can thereby be manufactured.

In the oriented-film formation apparatus 300 according to the above-mentioned embodiment, one pair of the regulating plates 303 between which the linear evaporation source 302a is interposed are provided, but one pair of the regulating plates 303 can also be provided on a short side (side orthogonal to the line direction) in a lateral direction of the linear evaporation source 302a.

Accordingly, since the circumference of the linear evaporation source 302a is surrounded with the regulating plates 303, the effect of uniformity of a material distribution by the above-described regulating plates 303 can largely be achieved.

When the height of the regulating plate 303 is large, the number of collisions of an inner surface of the regulating plate and the material, and the number of reflections can increase. The distribution can thereby be further uniform.

Therefore, it is preferable that the regulating plate 303 be provided as large as possible. However, since the size of the apparatus itself actually increases when the regulating plate is large, it is thereby desirable that regulating plate as large as possible for a space within an apparatus be arranged.

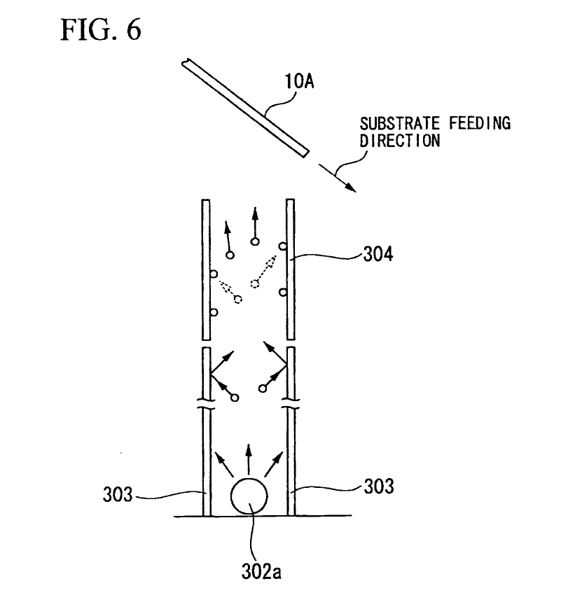

As shown in FIG. 6, an adhesion resistant plate 304 can be provided between the regulating plate 303 and the substrate 10A.

This adhesion resistant plate 304 is used to cause an unevaporated material of materials present between the substrate 10A and the regulating plate to be adhered on the substrate 10A.

It is desirable that the temperature of the adhesion resistant plate 304 be set to be lower than the temperature at which the material evaporates, for example, a substantially normal temperature.

This construction can prevent a material dispersed from a predetermined angle to the substrate 10A from adhering to the adhesion resistant plate 304 and prevent a material from adhering to an inner-wall surface of the evaporation chamber 308.

Consequently, the maintenance work within the evaporation chamber 308 can be reduced by preventing the material from adhering to the inside wall of the evaporation chamber 308. Thus, an apparatus having a low maintenance cost is provided.

In the oriented-film formation apparatus 300 of this embodiment, a material whose distribution is uniformly formed by the regulating plate 303 is film-formed on the substrate 10A. An oriented film having a high level of reliability in which a material of a given thickness is oriented can thereby be manufactured.

Since a conventional rubbing treatment is unnecessary when the oriented film is formed in the oriented-film formation apparatus 300, the degradation of display quality due to streaks formed on a film surface in the case where the conventional rubbing treatment is performed can be prevented. The yield can thereby be improved.

In the oriented-film formation apparatus 300, an organic-inorganic hybrid material is used as the evaporation source.

The organic-inorganic hybrid material has both an organic component and an inorganic component in the same molecules and has an inorganic backbone. It is a material of higher heat resistance when compared to a polymer material.

By using this organic-inorganic hybrid material as the evaporation source, the deterioration of composition of a material in an evaporation process can be prevented when compared to a conventional oriented-film formation apparatus using the polymer material as the evaporation source.

According to the oriented-film formation apparatus 300, reproducibility can be enhanced in an oriented-film formation apparatus for forming the oriented film having the desired characteristics by obliquely evaporating the material from the evaporation source on the substrate.

Since the oriented film made of the organic-inorganic hybrid material has superior heat resistance, the deterioration of composition of the oriented film due to be subjected to in a high-temperature environment can be prevented.

It is preferable that the melting point of the organic-inorganic hybrid material in the inorganic oriented-film formation apparatus 300 is higher than the temperature at which the oriented film is subjected to in the process of manufacturing a liquid crystal device having an oriented film.

Accordingly, the oriented film made of the organic-inorganic hybrid material can prevent the orientation regulating force from being lost due to melting in the process of manufacturing liquid crystal devices.

In the oriented-film formation apparatus 300 of this embodiment, it is preferable that a molecular amount of the organic-inorganic hybrid material is a molecular amount in which the composition of the organic-inorganic hybrid material does not deteriorate in the environment (vacuum environment and heating environment) in which evaporation is performed.

Accordingly, the composition of the organic-inorganic hybrid material can be prevented from deteriorating due to evaporation.

Therefore, the deterioration of composition of the oriented film can be more surely prevented from being subjected to in the high-temperature environment.

In the oriented-film formation apparatus 300 of this embodiment, silsesquioxanes are used as the organic-inorganic hybrid material.

Since the silsesquioxanes are a material superior in both heat resistance and light resistance, the silsesquioxanes are used as the organic-inorganic hybrid material. An oriented film superior in both heat resistance and light resistance can thereby be more reliably formed with a high level of reproducibility.

After the TFT array substrate 10 having the oriented film is formed by the oriented-film formation apparatus 300, the facing substrate 20 separated from the TFT array substrate 10 is produced.

Also in this case, the shading film 23, the common electrode 21, and the like are formed on the substrate 20A in the same method for producing the TFT array substrate 10 after the substrate 20A is prepared. Furthermore, the oriented film 60 is additionally formed thereon using the oriented-film formation apparatus 300 shown in FIG. 5. The facing substrate 20 can thereby be formed.

Thereafter, the above-described liquid crystal device can be manufactured by pasting the TFT array substrate 10 to the facing substrate 20 via a sealing agent and additionally connecting a predetermined wiring after setting a liquid crystal panel by injecting the liquid crystal from a liquid crystal inlet formed on the sealing agent.

For example, the case where the linear evaporation source 302a is used as the evaporation source 302 in the oriented-film formation apparatus 300 was described, but a point evaporation source 302b can be used as the evaporation source.

Hereinafter, an embodiment in which the point evaporation source 302b is used will be described.

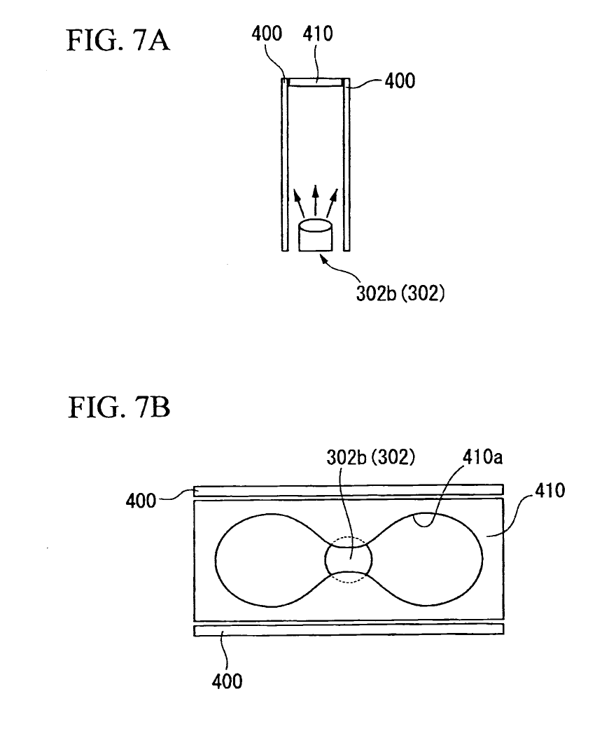

As shown in FIG. 7A, one pair of regulating plates 400 between which the point evaporation source 302b is interposed is provided.

In FIGS. 7A and 7B, the same parts in the construction shown in FIG. 5 are not shown and omitted.

Herein, there is irregularly distributed a material diffused in a direction in which no regulating plate 400 is provided since a material is radially diffused from the point evaporation source 302b.

Specifically, a material diffused to a side on which the regulating plate 400 is not provided is mostly distributed at a position corresponding to the point evaporation source 302b, that is, in a vertically upward direction of the point evaporation source 302b. Also, irregularity occurs due to a decrease in the material distribution when the material is in a lateral direction of the regulating plate 400, that is, the material is separated from the point evaporation source 302b.

Thus, between the regulating plates 400, a correcting plate 410 is provided in which an upper surface side faces the substrate 10A and a lower surface side faces the point evaporation source 302b.

In this embodiment, the correcting plate 410 is arranged in a vertically upward portion of the point evaporation source 302b.

In the correcting plate 410, an opening section 410a is formed in which an opening area at a position corresponding to the point evaporation source 302b (in the vertically upward portion of this embodiment) is small and the opening area gradually increases in the lateral direction of the regulating plate 400.

In this embodiment, a material from the point evaporation source 302b is evaporated on a surface of the substrate 10A by passing through the opening section 410a formed in the correcting plate 410 after reflection by an inner-wall surface of the regulating plate 400.

A material diffused from the point evaporation source 302b is mostly distributed in the vertically upward direction, but an opening area of the opening section 410a immediately above the point evaporation source 302b is small and a material amount is limited by passing through the opening section 410a and an amount of material passing through the correcting plate 410 is reduced.

As a material diffused from the point evaporation source 302b is apart from the evaporation source (in the lateral direction of the regulating plate 303), its distribution amount is reduced.

On the other hand, the amount of material passing through the opening section 410a is not limited since an opening area of the opening section 410a gradually increases in the lateral direction of the regulating plate.

Therefore, the material passing through the opening section 410a has an overall uniform distribution by relatively reducing the material distribution amount in a portion of a large distribution amount (a vertically upward portion of the point evaporation source 302b).

Even when only one pair of the regulating plates 303 is provided in the point evaporation source 302b by including the correcting plate 410, the material irregularity occurring on a side where the regulating plate 400 is not provided can be removed.

According to this construction, an oriented film of a uniform film thickness can be formed using the correcting plate 410 even when the point evaporation source 302b is used.

Projection Display Device

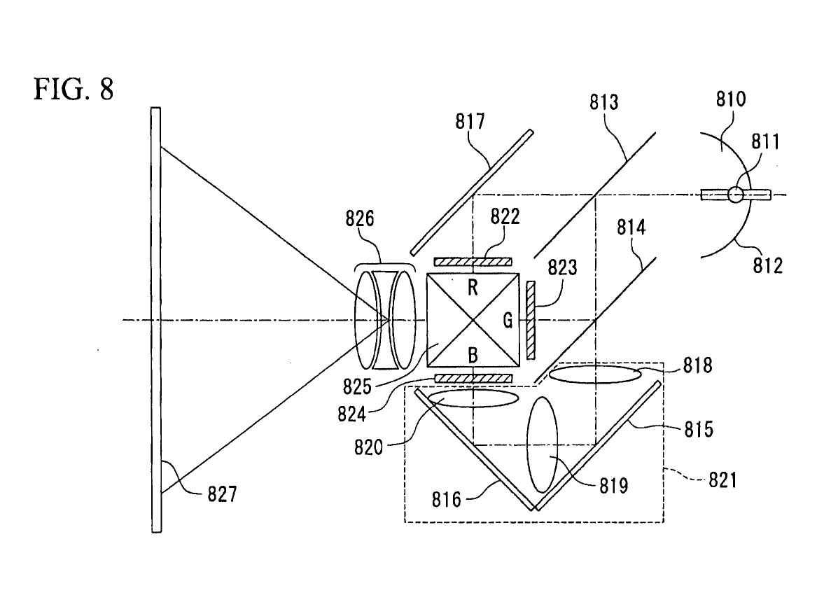

Next, a construction of a projection display device (projector) in which the liquid crystal device of the above-mentioned embodiment is provided as a light-modulation device will be described with reference to FIG. 8.

FIG. 8 is a schematic construction view showing main parts of the projection display device using the liquid crystal device of this embodiment as the light-modulation device.

In FIG. 8, reference numeral 810 is a light source, reference numerals 813 and 814 are dichroic mirrors, reference numerals 815, 816, and 817 are reflecting mirrors, reference numeral 818 is an entrance lens, reference numeral 819 is a relay lens, reference numeral 820 is an exit lens, reference numerals 822, 823, and 824 are liquid crystal light-modulation devices, reference numeral 825 is a cross dichroic prism, and reference numeral 826 is a projection lens.

The light source 810 includes a lamp 811 such as a metal halide lamp and a reflector 812 for reflecting light of the lamp.

The dichroic mirror 813 transmits red light of a light flux from the light source 810 and reflects blue light and green light

The transmitted red light is reflected by the reflecting mirror 817 and enters the photo-modulation section 822 for red light having a liquid crystal device of an example of the above-described invention.

On the other hand, the green light of color lights reflected by the dichroic mirror 813 is reflected by the dichroic mirror 814 reflecting the green light and enters the light-modulation device 823 for green light having a liquid crystal device of an example of the above-described invention.

The blue light is transmitted through the second dichroic mirror 814.

A light-guiding section 821 is provided on the optical-path of the blue light

The light-guiding section 821 constituted by a relay lens system including the entrance lens 818, the relay lens 819, and the exit lens 820 in order to compensate a difference from optical path lengths of green light and red light for blue light. The blue light is passed through the light-guiding section 821, and the blue light thereby enters the light-modulation device 824 for modulating the blue light. The light-modulation device 824 is a liquid crystal device of an example of the above-described invention.

The three color lights modulated by the light-modulation devices enter the cross dichroic prism 825.

The cross dichroic prism is formed by connecting four right-angle prisms, and on an inner face thereof, a dielectric multi-layer film for reflecting red light and a dielectric multi-layer film for reflecting blue light are formed so that these dielectric multi-layer films are across each other.

The three color lights are synthesized by the dielectric multi-layer films to form light expressing a color image.

The synthesized light is projected on a screen 827 by the projection lens 826 including the projection optical system.

The projection display device having the above-mentioned structure is provided with the liquid crystal device of the example of the above-described invention, and serves as, for example, a display device in which display quality is maintained for a long period without the problem of a rubbing streak as shown when a rubbing treatment is applied.

The technical scope of the invention is not limited to the above embodiments, and various modifications can be made without deviating from the gist of the invention.

For example, in the above-mentioned embodiment, silsesquioxanes are used as the organic-inorganic hybrid material.

However, the invention is not limited thereto, and Dialkoxy Tin Oxides of Dibutyl Tin Oxide, Diethyl Tin Oxide, Dimethyl Tin Oxide, Diphenyl Tin Oxide, and the like can be used as the organic-inorganic hybrid material.

For example, the liquid crystal device provided with TFT as switching elements was described as an example in the embodiment, but this invention is also applied to a liquid crystal device provided with two-terminal elements, thin film diodes, as switching elements.

The projection liquid crystal device was described as an example of the above-mentioned embodiment, but it is possible to apply a reflection-type liquid crystal device to this invention.

A liquid crystal device functioning in TN (Twisted Nematic) mode was described as an example in the embodiment, but it is also possible to apply this invention to a liquid crystal device functioning in VA (Vertical Alignment) mode.

A three-plate type projection display device (projector) was described as an example in the embodiment, but it is also possible to apply this invention to a single-plate type projection display device or a direct-view display device.

It is also possible to apply this invention to an electronic device other than the projector.

A portable telephone can be given as a specific example thereof.

The portable telephone is provided with a liquid crystal device relating to the above-mentioned embodiments or their modified examples in the display unit.

As other electronic devices, for example, IC cards, video cameras, PC computers, head-mount displays, fax devices with display functions, finders of digital cameras, portable TVs, DSP devices, PDAs, electronic notebooks, electric light notice boards, or displays for propagation and announcement, are given.

What is claimed is:

1. An oriented-film formation apparatus forming an oriented film on a substrate by obliquely evaporating a predetermined material in a vacuum state, the oriented-film formation apparatus comprising
an evaporation source having an organic-inorganic hybrid material.

2. The oriented-film formation apparatus according to claim 1, wherein
the melting point of the organic-inorganic hybrid material is higher than the temperature at which the oriented film is subjected to in a process of manufacturing a liquid crystal device having the oriented film.

3. The oriented-film formation apparatus according to claim 1, wherein
the molecular weight of the organic-inorganic hybrid material is the molecular weight so that the composition of the organic-inorganic hybrid material does not deteriorate in the vacuum state.

4. The oriented-film formation apparatus according to claim 1, wherein
the organic-inorganic hybrid material includes silsesquioxanes.

5. An oriented film used for a liquid crystal device, comprising
an organic-inorganic hybrid material.

6. The oriented film according to claim 5, wherein
the organic-inorganic hybrid material includes silsesquioxanes.
